(19) United States
(12) Patent Application Publication
(10) Pub. No.: US 2026/0293681 A1
(43) Pub. Date: Sep. 24, 2026

(54) SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/276,029

(22) Filed: Jul. 22, 2025

(30) Foreign Application Priority Data
Mar. 19, 2025 (KR) 10-2025-0035082

(51) Int. Cl. H01L 23/00; H01L 23/544

(52) U.S. Cl. CPC H10W 42/121; H10W 46/00; H10W 46/301; H10W 46/503

(57) ABSTRACT

A semiconductor device including a substrate including a chip region; a passivation layer located on the substrate; a redistribution insulating layer on the passivation layer; redistribution trenches located in the chip region, extending through the redistribution insulating layer into the passivation layer, and disposed spaced apart from each other in a first direction of an upper surface of the substrate; and a redistribution conductive layer disposed on side surfaces of the redistribution trenches, and including an upper surface that is located between an upper surface of the redistribution insulating layer and lower surfaces of the redistribution trenches.

### CROSS-REFERENCE TO RELATED APPLICATION

The present application claims priority under 35 U.S.C. § 119(a) to Korean Patent Application No. 10-2025-0035082 filed on Mar. 19, 2025, which is incorporated herein by reference in its entirety.

### BACKGROUND

### 1. Technical Field

Embodiments of the present disclosure relate generally to a semiconductor device and, in particular to a semiconductor device with an alignment key.

### 2. Related Art

Semiconductor chips are attracting attention as an important element in the electronics industry due to their characteristics such as miniaturization, multi-functionality and/or low manufacturing cost. As the electronics industry advances, semiconductor chips are gradually becoming more highly integrated. With this higher level of integration, the size of the chips is gradually decreasing, while the number of chips formed on a single wafer is increasing.

Semiconductor chips are manufactured on a single wafer and then are divided into individual semiconductor chips through a cutting process such as sawing or dicing. As semiconductor chips become more highly integrated, the difficulty of the process of cutting semiconductor chips increases. Therefore, new solutions are needed.

### SUMMARY

Embodiments of the present disclosure are directed to providing a semiconductor device in which a cutting defect occurring during a cutting process may be minimized.

Embodiments of the present disclosure are not limited to those set forth herein, and other unmentioned embodiments would be apparent to one of ordinary skill in the art from the following description.

In an embodiment of the present disclosure, a semiconductor device may include a substrate including a chip region, a passivation layer located on the substrate, a redistribution insulating layer on the passivation layer, redistribution trenches located in the chip region, extending through the redistribution insulating layer into the passivation layer, and disposed spaced apart from each other in a first direction of an upper surface of the substrate, and a redistribution conductive layer disposed on side surfaces of the redistribution trenches, and including an upper surface that is located between an upper surface of the redistribution insulating layer and lower surfaces of the redistribution trenches.

In an embodiment of the present disclosure, a semiconductor device may include a substrate including a chip region, a conductive layer on the substrate, a passivation layer on the conductive layer, a redistribution insulating layer on the passivation layer, redistribution trenches located in the chip region, penetrating the redistribution insulating layer and the passivation layer, and overlapping with the conductive layer; and a redistribution conductive layer disposed on side surfaces of the redistribution trenches, and including an upper surface that is located between an upper surface of the redistribution insulating layer and lower surfaces of the redistribution trenches.

In an embodiment of the present disclosure, a semiconductor device may include a conductive layer on a substrate, a passivation layer on the conductive layer, a redistribution insulating layer on the passivation layer, redistribution trenches located in a chip region of the substrate, passing through the redistribution insulating layer and the passivation layer, and overlapping with the conductive layer, a redistribution conductive layer disposed on side surfaces of the redistribution trenches, the redistribution conductive layer including an upper surface that is located between an upper surface of the redistribution insulating layer and a lower surface of the redistribution trenches, and a guard ring disposed in a guard ring region of the substrate, wherein the redistribution trenches overlap with the guard ring, and wherein the guard ring includes a guard conductive layer that is disposed under the redistribution trenches, and at least a portion of the redistribution conductive layer contacts an upper surface of the guard conductive layer.

According to embodiments of the present disclosure, it is possible to provide a semiconductor device in which a cutting defect occurring during a cutting process may be minimized.

The advantages of the embodiments of the present disclosure are not limited to the foregoing advantages, and other advantages will be apparent to one of ordinary skill in the art from the following detailed description.

### BRIEF DESCRIPTION OF THE DRAWINGS

The embodiments of the present disclosure will be more fully understood from the following detailed description and the accompanying drawings, which are provided for illustration only and are not intended to limit the embodiments.

FIG. 1 is a simplified schematic view illustrating a planar structure of a semiconductor device according to an embodiment of the present disclosure.

FIG. 2 is an enlarged view of an alignment key region AR of FIG. 1.

FIG. 3 is a simplified schematic view illustrating an example of the cross-sectional structure of a part indicated by a line I-I′ of FIG. 2.

FIG. 4 is a simplified schematic view illustrating a cross-sectional structure of a part indicated by a line II-II′ of FIG. 2.

FIG. 5 is a simplified schematic view illustrating another cross-sectional structure of the part indicated by the line I-I′ of FIG. 2.

FIG. 6 is a simplified schematic view illustrating another cross-sectional structure of the part indicated by the line II-II′ of FIG. 2.

FIG. 7 is a simplified schematic view illustrating another cross-sectional structure of the part indicated by the line I-I′ of FIG. 2.

FIG. 8 is a simplified schematic view illustrating another cross-sectional structure of the part indicated by the line II-II′ of FIG. 2.

FIG. 9 is a simplified schematic view illustrating another cross-sectional structure of the part indicated by the line I-I′ of FIG. 2.

FIG. 10 is a simplified schematic view illustrating another cross-sectional structure of the part indicated by the line II-II′ of FIG. 2.

FIG. 11 is a simplified schematic view illustrating a planar structure of a semiconductor device according to an embodiment of the present disclosure.

FIG. 12 is an enlarged view of an alignment key region AR of FIG. 11.

FIG. 13 is a simplified schematic view illustrating a cross-sectional structure of a part indicated by a line III-III′ of FIG. 12.

FIG. 14 is a simplified schematic view illustrating a cross-sectional structure of a part indicated by a line IV-IV′ of FIG. 12.

FIG. 15 is a simplified schematic view illustrating a cross-sectional structure of the part indicated by the line III-III′ of FIG. 12.

FIG. 16 is a simplified schematic view illustrating a cross-sectional structure of the part indicated by the line IV-IV′ of FIG. 12.

### DETAILED DESCRIPTION

Embodiments of the present disclosure are described in detail with reference to the accompanying drawings. Specific structural or functional descriptions of embodiments are provided as examples to describe the technical concepts that are disclosed in the present disclosure. Examples or embodiments in accordance with the technical concepts may be carried out in various forms, and the scope of the present disclosure is not limited only to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one embodiment, and the second element may be named as a first element in another embodiment.

In the description, when an element included in an embodiment is described in singular form, the element may be interpreted to include a plurality of elements performing the same or similar functions.

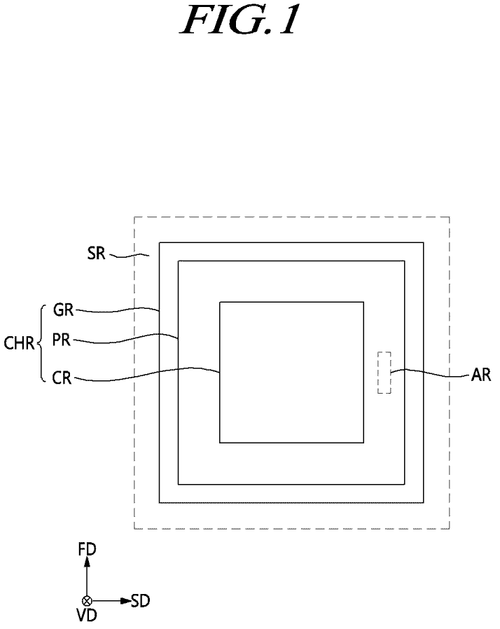

FIG. 1 is a simplified schematic view illustrating a planar structure of a semiconductor device according to an embodiment of the present disclosure.

Referring to FIG. 1, the semiconductor device according to the embodiments of the present disclosure may include a chip region CHR and a scribe lane region SR. The chip region CHR may refer to a region that includes memory cells and peripheral circuits making up one semiconductor chip. The scribe lane region SR may refer to a region where cutting occurs when semiconductor chips are manufactured together on one wafer and are then divided into individual chips. The scribe lane region SR may surround the chip region CHR.

The chip region CHR may include a cell region CR, a peripheral region PR and a guard ring region GR. The cell region CR may refer to a region where memory cells are disposed. The memory cells may include, for example, dynamic random access memory (DRAM) cells, static random access memory (SRAM) cells, flash memory cells, magnetoresistive random access memory (MRAM) cells, phase change random access memory (PRAM) cells, ferroelectric random access memory (FRAM) cells, resistive random access memory (RRAM) cells, or combinations thereof. In an embodiment, the memory cells may include DRAM cells.

The peripheral region PR may refer to a region where peripheral circuits for supplying various signals and voltages to memory cells are disposed. The peripheral region PR is disposed around the cell region CR. The peripheral region PR may surround the cell region CR.

The guard ring region GR may refer to a region where a guard ring is disposed. In an embodiment, the guard ring may serve to protect the memory cells included in the cell region CR and the peripheral circuits included in the peripheral region PR. The guard ring region GR is disposed around the peripheral region PR. The guard ring region GR may surround the peripheral region PR.

In an embodiment, at least one alignment key region AR may be disposed in the peripheral region PR. The alignment key region AR may refer to a region where one or more alignment keys are disposed. An alignment key may refer to a pattern used to align semiconductor devices when forming the semiconductor devices.

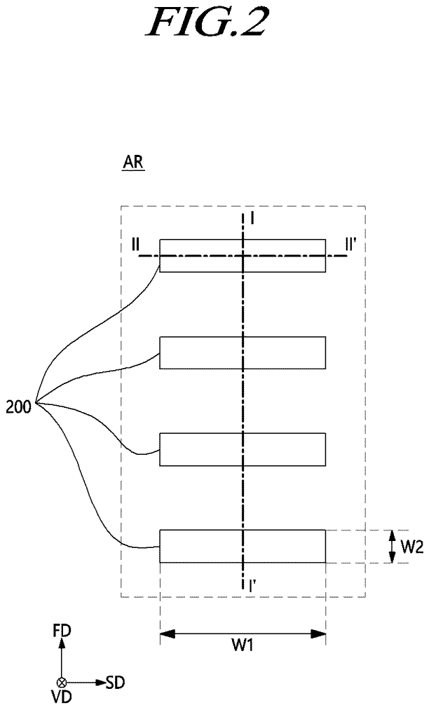

FIG. 2 is an enlarged view of the alignment key region AR of FIG. 1.

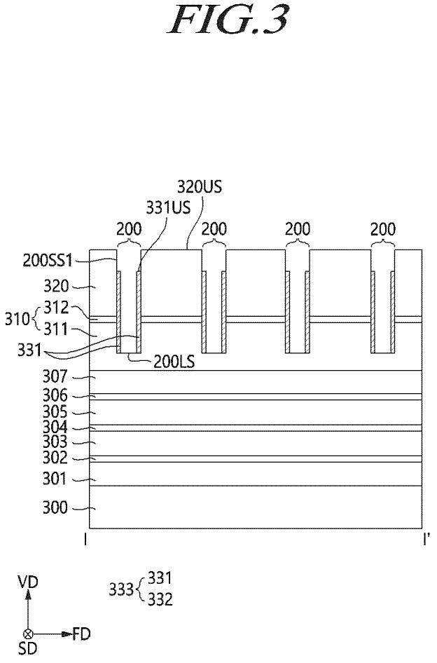

Referring to FIG. 2, four redistribution trenches may be included in the alignment key region AR. However, although four redistribution trenches are illustrated for the embodiment of FIG. 2, the number of the redistribution trenches is not limited to this. Generally at least one redistribution trench 200 may be disposed in the alignment key region AR. In an embodiment, the redistribution trench 200 may be a key that is used to align an etch mask in a process of etching a redistribution conductive layer 333 to be described later with reference to FIG. 3.

The redistribution trenches 200 may be disposed spaced apart from each other in a first direction FD. In an embodiment, a width W2 of the redistribution trench 200 in the first direction FD may be thinner than a width W1 of the redistribution trench 200 in a second direction SD.

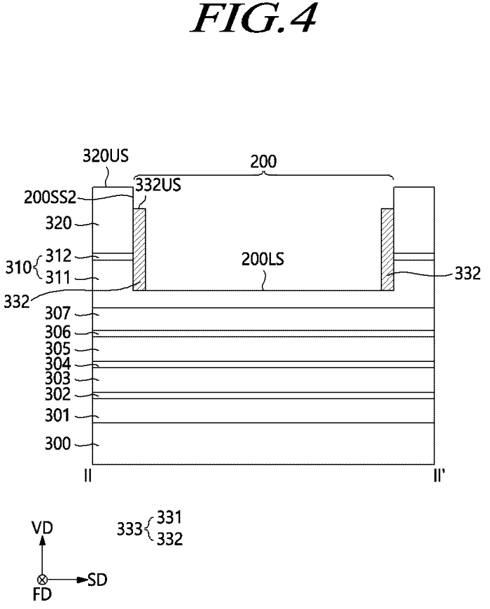

FIG. 3 is a simplified schematic view illustrating a cross-sectional structure of a part indicated by a line I-I′ of FIG. 2. FIG. 4 is a simplified schematic view illustrating a cross-sectional structure of a part indicated by a line II-II′ of FIG. 2.

Referring to FIG. 3 and FIG. 4, a semiconductor device according to an embodiment of the present disclosure may include a substrate 300, a first insulating layer 301, a first interlayer insulating layer 302, a second insulating layer 303, a second interlayer insulating layer 304, a third insulating layer 305, a third interlayer insulating layer 306, a fourth insulating layer 307, a passivation layer 310, a redistribution insulating layer 320, and a redistribution conductive layer 333. The passivation layer 310 may include a first passivation layer 311 and a second passivation layer 312. The redistribution conductive layer 333 may include a first redistribution conductive layer 331 and a second redistribution conductive layer 332.

The substrate 300 may include a semiconductor substrate such as a silicon wafer or a silicon-on-insulator (SOI) wafer. The substrate 300 may include a III-V group semiconductor substrate, for example, a compound semiconductor substrate such as gallium arsenide (GaAs). The substrate 300 may include monocrystalline silicon, polysilicon, amorphous silicon, monocrystalline silicon germanium, polycrystalline silicon germanium, carbon-doped silicon, or a combination thereof.

The first insulating layer 301 is disposed on the substrate 300. The first insulating layer 301 may include silicon oxide, silicon nitride, silicon oxynitride, low-k dielectric, high-k dielectric, or a combination thereof.

The first interlayer insulating layer 302 is disposed on the first insulating layer 301. The first interlayer insulating layer 302 may include silicon oxide, silicon nitride, silicon oxynitride, low-k dielectric, high-k dielectric, or a combination thereof.

The second insulating layer 303, the second interlayer insulating layer 304, the third insulating layer 305, the third interlayer insulating layer 306 and the fourth insulating layer 307 are sequentially disposed on the first interlayer insulating layer 302. In an embodiment, the second insulating layer 303, the third insulating layer 305 and the fourth insulating layer 307 may include the same material as the first insulating layer 301. The second interlayer insulating layer 304 and the third interlayer insulating layer 306 may include the same material as the first interlayer insulating layer 302.

The passivation layer 310 is disposed on the fourth insulating layer 307. The first passivation layer 311 is disposed on the fourth insulating layer 307. In an embodiment, the first passivation layer 311 may include high density plasma (HDP) oxide. The second passivation layer 312 is disposed on the first passivation layer 311. In an embodiment, the second passivation layer 312 may include silicon nitride.

The redistribution insulating layer 320 is disposed on the passivation layer 310. The redistribution insulating layer 320 may include silicon oxide, silicon nitride, silicon oxynitride, low-k dielectric, high-k dielectric, or a combination thereof.

The redistribution trench 200 may extend through the redistribution insulating layer 320 into the passivation layer 310. For example, the redistribution trench 200 may extend through the redistribution insulating layer 320 and the second passivation layer 312 into the first passivation layer 311. In an embodiment, by the redistribution trench 200, the side surface and the upper surface of the first passivation layer 311, the side surface of the second passivation layer 312, and the side surface of the redistribution insulating layer 320 may be exposed. A lower surface 200LS of the redistribution trench 200 may be spaced apart from the lower surface of the first passivation layer 311. In an embodiment, the lower surface 200LS of the redistribution trench 200 may be located between the upper surface and the lower surface of the first passivation layer 311. In an embodiment, at least portions of first side surfaces 200SS1 of the redistribution trench 200 that face each other in the first direction FD may be exposed.

The first redistribution conductive layer 331 may be disposed on the first side surfaces 200SS1 of the redistribution trench 200 that face each other in the first direction FD. The first redistribution conductive layer 331 may cover the first side surfaces 200SS1 and the lower surface 200LS of the redistribution trench 200. The side surface of the first redistribution conductive layer 331 may contact the side surface of the redistribution insulating layer 320, the side surface of the second passivation layer 312, and the side surface of the first passivation layer 311. The lower surface of the first redistribution conductive layer 331 may contact the first passivation layer 311. In an embodiment, portions of the first redistribution conductive layer 331 may be disposed spaced apart from each other in one redistribution trench 200. In an embodiment, at least a portion of the upper surface of the first passivation layer 311 may be exposed.

An upper surface 331US of the first redistribution conductive layer 331 may be located between an upper surface 320US of the redistribution insulating layer 320 and the lower surface 200LS of the redistribution trench 200. In an embodiment, the upper surface 331US of the first redistribution conductive layer 331 may be located between an upper surface 320US of the redistribution insulating layer 320 and a lower surface of the redistribution insulating layer 320. A lower surface of the first redistribution conductive layer 331 may be in direct contact with the lower surface 200LS of the redistribution trench 200.

The first redistribution conductive layer 331 may include a conductive material such as, for example, metal, metal oxide, metal nitride, metal silicide, polysilicon, conductive carbon or a combination thereof. In an embodiment, the first redistribution conductive layer 331 may include aluminum (Al).

Referring to FIG. 4, the second redistribution conductive layer 332 may be disposed on second side surfaces 200SS2 of the redistribution trench 200 that face each other in the second direction SD. The second redistribution conductive layer 332 may cover the second side surfaces 200SS2 and the lower surface 200LS of the redistribution trench 200. The side surface of the second redistribution conductive layer 332 may contact the side surface of the redistribution insulating layer 320, the side surface of the second passivation layer 312, and the side surface of the first passivation layer 311. The lower surface of the second redistribution conductive layer 332 may contact the first passivation layer 311. An upper surface 332US of the second redistribution conductive layer 332 may be located between the upper surface 320US of the redistribution insulating layer 320 and the lower surface 200LS of the redistribution trench 200. In an embodiment, the upper surface 332US of the second redistribution conductive layer 332 may be located between the upper surface 320US of the redistribution insulating layer 320 and the lower surface of the redistribution insulating layer 320. A lower surface of the second redistribution conductive layer 332 may be in direct contact with the lower surface 200LS of the redistribution trench 200.

In an embodiment, portions of the second redistribution conductive layer 332 may be disposed spaced apart from each other in one redistribution trench 200. In an embodiment, at least a portion of the upper surface of the first passivation layer 311 may be exposed. The second redistribution conductive layer 332 may include the same material as the first redistribution conductive layer 331.

In an embodiment, a process of forming the redistribution conductive layer 333 may include a process of depositing a conductive material on the upper surface 320US of the redistribution insulating layer 320, the side surfaces 200SS1 and 200SS2 of the redistribution trench 200 and the lower surface 200LS of the redistribution trench 200, depositing an insulating material on the conductive material, and then etching at least portions of the conductive material and the insulating material. In an embodiment, the insulating material may include oxide that has a higher etch rate than the redistribution insulating layer 320. Because the etch rate of the insulating material is high, during a course in which the conductive material and the insulating material located on the upper surface 320US of the redistribution insulating layer 320 are removed, at least portions of the conductive material disposed on the side surfaces 200SS1 and 200SS2 of the redistribution trench 200 may be removed together. Accordingly, as illustrated in FIG. 3 and FIG. 4, the upper surface of the redistribution conductive layer 333 may be located between the upper surface 320US of the redistribution insulating layer 320 and the lower surface 200LS of the redistribution trench 200.

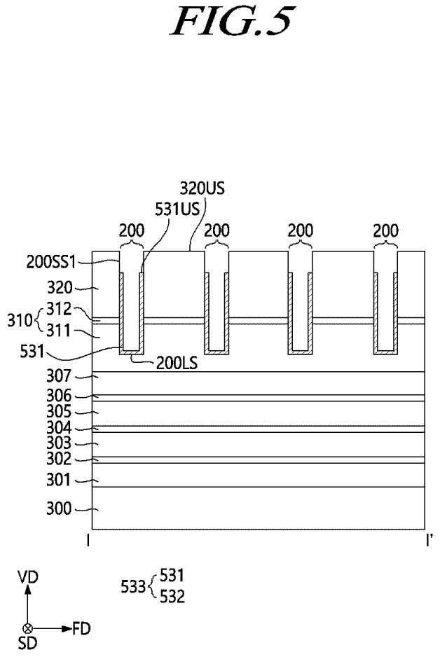

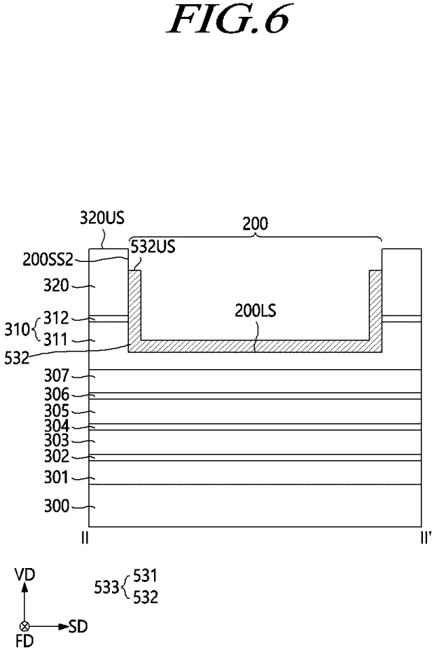

FIG. 5 is a simplified schematic view illustrating another cross-sectional structure of the part indicated by the line I-I′ of FIG. 2. FIG. 6 is a simplified schematic view illustrating another cross-sectional structure of the part indicated by the line II-II′ of FIG. 2.

Referring to FIG. 5 and FIG. 6, a semiconductor device according to an embodiment of the present disclosure may include a substrate 300, a first insulating layer 301, a first interlayer insulating layer 302, a second insulating layer 303, a second interlayer insulating layer 304, a third insulating layer 305, a third interlayer insulating layer 306, a fourth insulating layer 307, a passivation layer 310, a redistribution insulating layer 320, and a redistribution conductive layer 533. The passivation layer 310 may include a first passivation layer 311 positioned on the fourth insulating layer 307 and a second passivation layer 312 positioned over the first passivation layer 311. The redistribution conductive layer 533 may include a first redistribution conductive layer 531 and a second redistribution conductive layer 532.

In the following, any descriptions for components that are substantially the same as those included in the semiconductor device described above with reference to FIG. 3 and FIG. 4 may be omitted.

Referring to FIG. 5, the first redistribution conductive layer 531 may be disposed on first side surfaces 200SS1 of the redistribution trench 200 that face each other in the first direction FD. The first redistribution conductive layer 531 may cover the first side surfaces 200SS1 and also a lower surface 200LS of the redistribution trench 200. In an embodiment, the first redistribution conductive layer 531 may completely cover the lower surface 200LS of the redistribution trench 200. The side surface of the first redistribution conductive layer 531 may contact the side surface of the redistribution insulating layer 320, the side surface of the second passivation layer 312, and the side surface of the first passivation layer 311. The lower surface of the first redistribution conductive layer 531 may contact the first passivation layer 311. In an embodiment, the first redistribution conductive layer 531 may completely cover the upper surface of the first passivation layer 311 that overlaps the redistribution trench 200. In an embodiment, the side surface and the upper surface of the first passivation layer 311 might not be exposed.

An upper surface 531US of the first redistribution conductive layer 531 may be located between an upper surface 320US of the redistribution insulating layer 320 and the lower surface 200LS of the redistribution trench 200. In an embodiment, the upper surface 531US of the first redistribution conductive layer 531 may be located between the upper surface 320US of the redistribution insulating layer 320 and the lower surface of the redistribution insulating layer 320. A lower surface of the first redistribution conductive layer 531 may directly contact the lower surface 200LS of the redistribution trench 200.

Referring to FIG. 6, the second redistribution conductive layer 532 may be disposed on second side surfaces 200SS2 of the redistribution trench 200 that face each other in the second direction SD. The second redistribution conductive layer 532 may cover the second side surfaces 200SS2 and the lower surface 200LS of the redistribution trench 200. In an embodiment, the second redistribution conductive layer 532 may completely cover the lower surface 200LS of the redistribution trench 200. The side surface of the second redistribution conductive layer 532 may contact the side surface of the redistribution insulating layer 320, the side surface of the second passivation layer 312, and the side surface of the first passivation layer 311. The lower surface of the second redistribution conductive layer 532 may contact the first passivation layer 311. An upper surface 532US of the second redistribution conductive layer 532 may be located between the upper surface 320US of the redistribution insulating layer 320 and a lower surface of the redistribution insulating layer 320. In an embodiment, the upper surface 532US of the second redistribution conductive layer 532 may be located between the upper surface 320US of the redistribution insulating layer 320 and a lower surface of the redistribution insulating layer 320. A lower surface of the second redistribution conductive layer 532 may directly contact the lower surface of the redistribution insulating layer 320.

In an embodiment, the second redistribution conductive layer 532 may completely cover the upper surface of the first passivation layer 311 that overlaps the redistribution trench 200. In an embodiment, the side surface and the upper surface of the first passivation layer 311 might not be exposed. The second redistribution conductive layer 532 may include the same material as the first redistribution conductive layer 531.

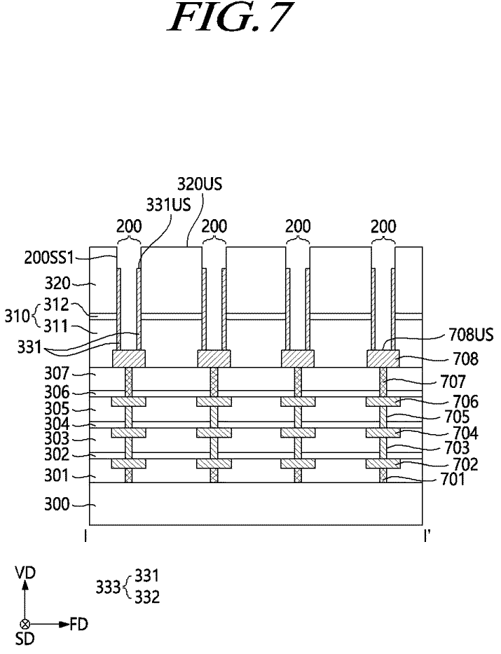

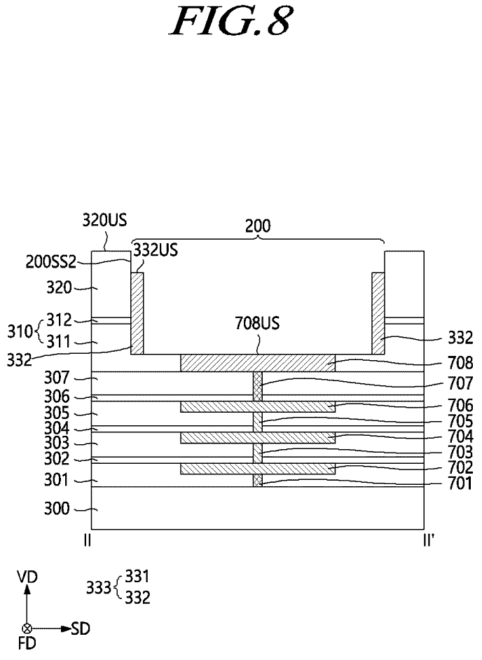

FIG. 7 is a simplified schematic view illustrating another cross-sectional structure of the part indicated by the line I-I′ of FIG. 2. FIG. 8 is a simplified schematic view illustrating another cross-sectional structure of the part indicated by the line II-II′ of FIG. 2.

Referring to FIG. 7 and FIG. 8, a semiconductor device according to an embodiment of the present disclosure may include a substrate 300, a first insulating layer 301, a first contact 701, a first conductive layer 702, a first interlayer insulating layer 302, a second insulating layer 303, a second contact 703, a second conductive layer 704, a second interlayer insulating layer 304, a third insulating layer 305, a third contact 705, a third conductive layer 706, a third interlayer insulating layer 306, a fourth insulating layer 307, a fourth contact 707, a fourth conductive layer 708, a passivation layer 310, a redistribution insulating layer 320, and a redistribution conductive layer 333. The passivation layer 310 may include a first passivation layer 311 and a second passivation layer 312. The redistribution conductive layer 333 may include a first redistribution conductive layer 331 and a second redistribution conductive layer 332.

Referring to FIG. 7, the first contact 701 may be connected to the substrate 300 by penetrating the first insulating layer 301. The first conductive layer 702 may be connected to the first contact 701. The upper surface of the first conductive layer 702 may form the same or substantially the same plane as the upper surface of the first insulating layer 301.

The second contact 703 may be connected to the first conductive layer 702 by penetrating the second insulating layer 303 and the first interlayer insulating layer 302. The second conductive layer 704 may be connected to the second contact 703, and in particular, a lower surface of the second conductive layer 704 may be connected to the upper surface of the second contact 703. The upper surface of the second conductive layer 704 may be coplanar with the upper surface of the second insulating layer 303. That is, the upper surface of the second conductive layer 704 may form the same or substantially the same plane as the upper surface of the second insulating layer 303.

The third contact 705 may be connected to the second conductive layer 704 by penetrating the third insulating layer 305 and the second interlayer insulating layer 304. In particular, the lower surface of the third contact 705 may be connected to the upper surface of the second conductive layer 704. The third conductive layer 706 may be connected to the third contact 705. In particular, a lower surface of the third conductive layer 706 may be connected to an upper surface of the third contact 705. The upper surface of the third conductive layer 706 may be coplanar with the upper surface of the third insulating layer 305, i.e., the upper surface of the third conductive layer 706 may form the same or substantially the same plane as the upper surface of the third insulating layer 305.

The fourth contact 707 may be connected to the third conductive layer 706 by penetrating the fourth insulating layer 307 and the third interlayer insulating layer 306. In particular, a lower surface of the fourth contact 707 may be connected to the upper surface of the third conductive layer 706. The fourth conductive layer 708 may be connected to the fourth contact 707. In particular, the lower surface of the fourth conductive layer 708 may be connected to the upper surface of the fourth contact 707. The lower surface of the fourth conductive layer 708 may be coplanar with the lower surface of the first passivation layer 311, i.e., the lower surface of the fourth conductive layer 708 may form the same or substantially the same plane as the lower surface of the first passivation layer 311.

The first contact 701, the first conductive layer 702, the second contact 703, the second conductive layer 704, the third contact 705, the third conductive layer 706, the fourth contact 707 and the fourth conductive layer 708 may include a conductive material such as, for example, metal, metal oxide, metal nitride, metal silicide, polysilicon, conductive carbon or a combination thereof.

The first redistribution conductive layer 331 may be connected to the fourth conductive layer 708. The lower surface of the first redistribution conductive layer 331 may contact an upper surface 708US of the fourth conductive layer 708. In an embodiment, portions of the first redistribution conductive layer 331 may be disposed spaced apart from each other in one redistribution trench 200. In an embodiment, at least a portion of the upper surface 708US of the fourth conductive layer 708 may be exposed.

An upper surface 331US of the first redistribution conductive layer 331 may be located between an upper surface 320US of the redistribution insulating layer 320 and the upper surface 708US of the fourth conductive layer 708. In an embodiment, the upper surface 331US of the first redistribution conductive layer 331 may be located between an upper surface 320US of the redistribution insulating layer 320 and a lower surface of the redistribution insulating layer 320.

Referring to FIG. 8, in an embodiment, the second redistribution conductive layer 332 might not be connected to the fourth conductive layer 708. The lower surface of the second redistribution conductive layer 332 may contact the first passivation layer 311. However, the embodiments of the present disclosure are not limited thereto, and in some embodiments, the lower surface of the second redistribution conductive layer 332 may contact the upper surface 708US of the fourth conductive layer 708. In an embodiment, portions of the second redistribution conductive layer 332 may be disposed spaced apart from each other in one redistribution trench 200. In the illustrated embodiment of FIG. 8 an entire upper surface 708US of the fourth conductive layer 708 is exposed by the redistribution trench 200. However, the embodiment may not be limited in this way and in another embodiment, or a variation of the present embodiment, at least a portion of the upper surface 708US of the fourth conductive layer 708 may be exposed.

An upper surface 332US of the second redistribution conductive layer 332 may be located closer to the upper surface 708US of the fourth conductive layer 708 than the upper surface 320US of the redistribution insulating layer 320. The upper surface 332US of the second redistribution conductive layer 332 may be located between the upper surface 320US of the redistribution insulating layer 320 and the upper surface 708US of the fourth conductive layer 708. In an embodiment, the upper surface 332US of the second redistribution conductive layer 332 may be located between the upper surface 320US of the redistribution insulating layer 320 and the lower surface of the redistribution insulating layer 320.

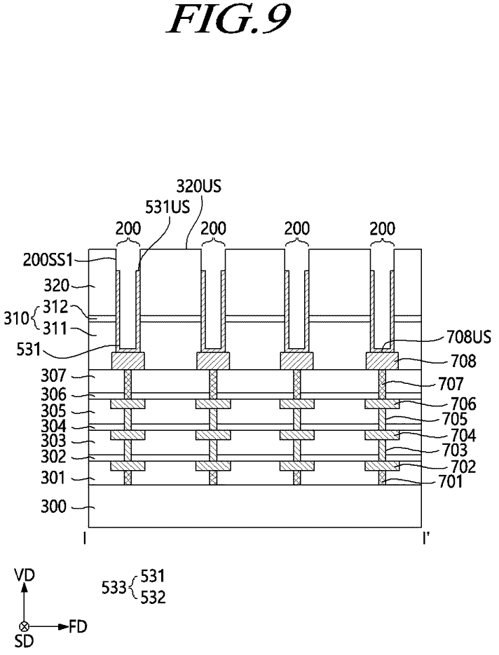

FIG. 9 is a simplified schematic view illustrating another cross-sectional structure of the part indicated by the line I-I′ of FIG. 2.

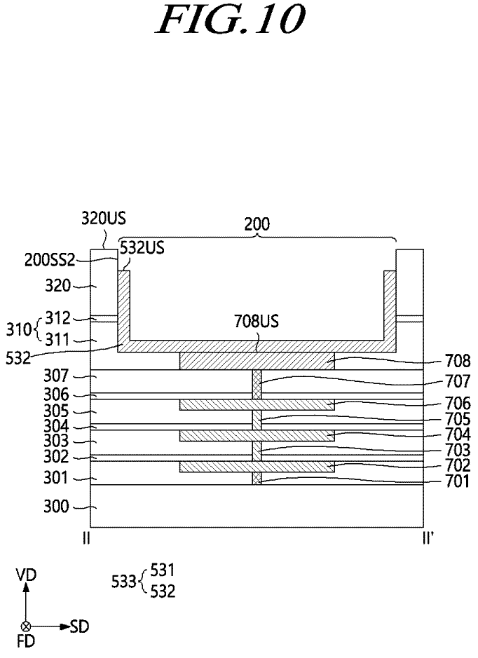

FIG. 10 is a simplified schematic view illustrating another cross-sectional structure of the part indicated by the line II-II′ of FIG. 2.

Referring to FIG. 9 and FIG. 10, a semiconductor device according to an embodiment of the present disclosure may include a substrate 300, a first insulating layer 301, a first contact 701, a first conductive layer 702, a first interlayer insulating layer 302, a second insulating layer 303, a second contact 703, a second conductive layer 704, a second interlayer insulating layer 304, a third insulating layer 305, a third contact 705, a third conductive layer 706, a third interlayer insulating layer 306, a fourth insulating layer 307, a fourth contact 707, a fourth conductive layer 708, a passivation layer 310, a redistribution insulating layer 320, and a redistribution conductive layer 533. The passivation layer 310 may include a first passivation layer 311 positioned on the fourth insulating layer 307 and a second passivation layer 312 positioned on the first passivation layer 311. The redistribution conductive layer 533 may include a first redistribution conductive layer 531 and a second redistribution conductive layer 532.

In the following, any descriptions for components that are substantially the same as those included in the semiconductor device described above with reference to FIG. 7 and FIG. 8 may be omitted.

Referring to FIG. 9, in an embodiment, the first redistribution conductive layer 531 may completely cover a lower surface of the redistribution trench 200. The side surface of the first redistribution conductive layer 531 may contact the side surface of the redistribution insulating layer 320, the side surface of the second passivation layer 312, and the side surface of the first passivation layer 311. The lower surface of the first redistribution conductive layer 531 may contact the fourth conductive layer 708, and, in particular an upper surface 708US of the fourth conductive layer 708. In an embodiment, the upper surface 708US of the fourth conductive layer 708 might not be exposed.

An upper surface 531US of the first redistribution conductive layer 531 may be located between an upper surface 320US of the redistribution insulating layer 320 and the upper surface 708US of the fourth conductive layer 708. In an embodiment, an upper surface 531US of the first redistribution conductive layer 531 may be located between an upper surface 320US of the redistribution insulating layer 320 and a lower surface of the redistribution insulating layer 320.

Referring to FIG. 10, in an embodiment, the second redistribution conductive layer 532 may completely cover the lower surface of the redistribution trench 200. The side surface of the second redistribution conductive layer 532 may contact the side surface of the redistribution insulating layer 320, the side surface of the second passivation layer 312, and the side surface of the first passivation layer 311. The lower surface of the second redistribution conductive layer 532 may contact the fourth conductive layer 708.

An upper surface 532US of the second redistribution conductive layer 532 may be located between the upper surface 320US of the redistribution insulating layer 320 and the upper surface 708US of the fourth conductive layer 708. In an embodiment, the upper surface 532US of the second redistribution conductive layer 532 may be located between the upper surface 320US of the redistribution insulating layer 320 and the lower surface of the redistribution insulating layer 320.

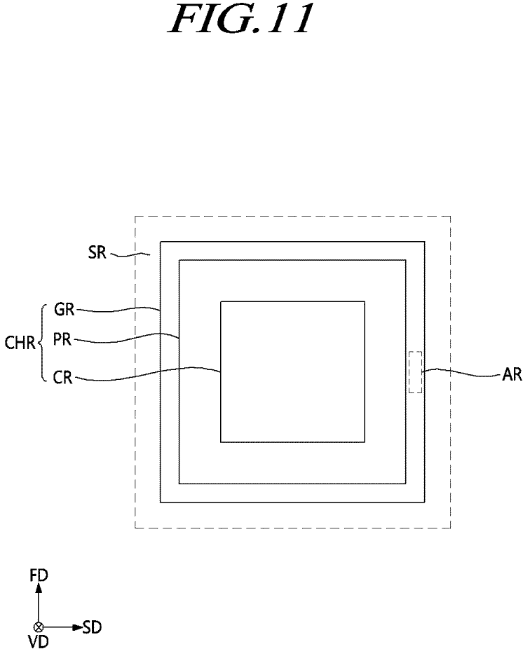

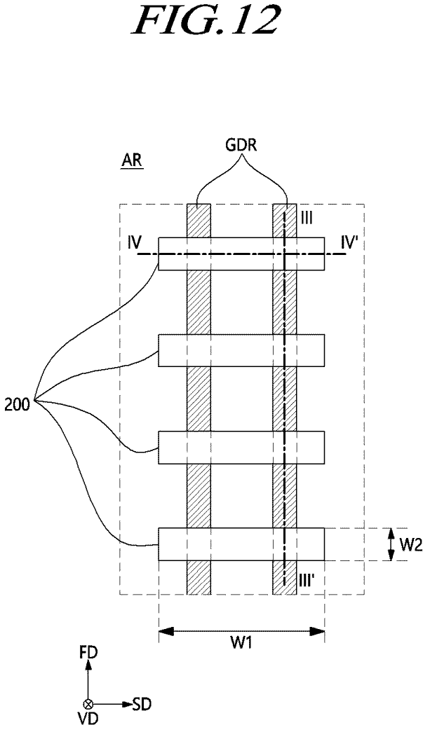

FIG. 11 is a simplified schematic view illustrating a planar structure of a semiconductor device according to an embodiment of the present disclosure. FIG. 12 is an enlarged view of an alignment key region AR of FIG. 11.

Referring to FIG. 11 and FIG. 12, the alignment key region AR may be disposed in a guard ring region GR. However, the location of the alignment key region AR is not limited thereto. For example, the alignment key region AR may be disposed to overlap both a peripheral region PR and the guard ring region GR. Alternatively, the alignment key region AR may be disposed to overlap with the guard ring region GR and a scribe lane region SR.

Referring to FIG. 12, a redistribution trench 200 may overlap a guard ring GDR. The guard ring GDR may extend in the first direction FD. In an embodiment, the redistribution trench 200 may be disposed to intersect the guard ring GDR.

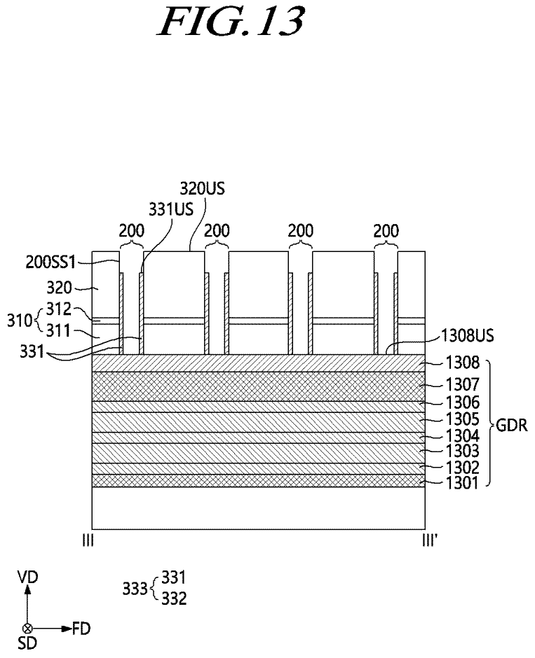

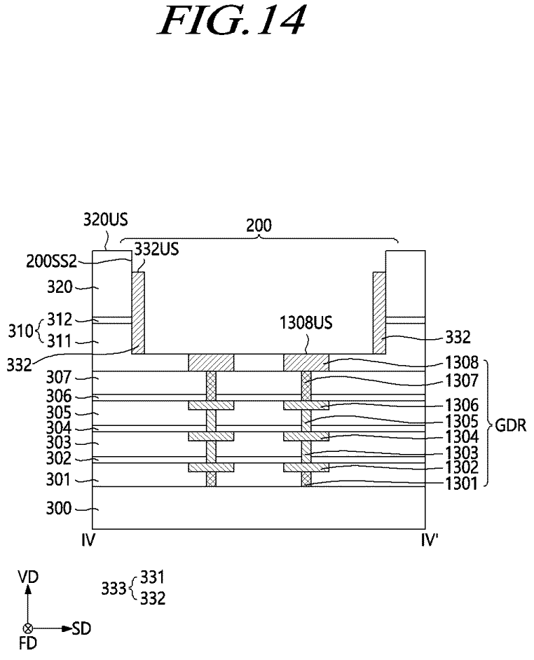

FIG. 13 is a simplified schematic view illustrating a cross-sectional structure of a part indicated by a line III-III′ of FIG. 12. FIG. 14 is a simplified schematic view illustrating a cross-sectional structure of a part indicated by a line IV-IV′ of FIG. 12.

Referring to FIG. 13 and FIG. 14, a semiconductor device according to an embodiment of the present disclosure may include a substrate 300, a first insulating layer 301, a first interlayer insulating layer 302, a second insulating layer 303, a second interlayer insulating layer 304, a third insulating layer 305, a third interlayer insulating layer 306, a fourth insulating layer 307, a passivation layer 310, a redistribution insulating layer 320, and a redistribution conductive layer 333. The passivation layer 310 may include a first passivation layer 311 and a second passivation layer 312. The redistribution conductive layer 333 may include a first redistribution conductive layer 331, a second redistribution conductive layer 332, and the guard ring GDR.

The guard ring GDR may include a first guard contact 1301, a first guard conductive layer 1302, a second guard contact 1303, a second guard conductive layer 1304, a third guard contact 1305, a third guard conductive layer 1306, a fourth guard contact 1307, and a fourth guard conductive layer 1308.

The first guard contact 1301 may be connected to the substrate 300 by penetrating the first insulating layer 301. The first guard conductive layer 1302 may be connected to the first guard contact 1301. The upper surface of the first guard conductive layer 1302 may form the same or substantially the same plane as the upper surface of the first insulating layer 301. The first guard contact 1301 and the first guard conductive layer 1302 may be disposed at the same layers as the first contact 701 and the first conductive layer 702, respectively, described above with reference to FIG. 7.

The second guard contact 1303 may be connected to the first guard conductive layer 1302 by penetrating the second insulating layer 303 and the first interlayer insulating layer 302. The second guard conductive layer 1304 may be connected to the second guard contact 1303. The upper surface of the second guard conductive layer 1304 may form the same or substantially the same plane as the upper surface of the second insulating layer 303. The second guard contact 1303 and the second guard conductive layer 1304 may be disposed at the same layers as the second contact 703 and the second conductive layer 704, respectively, described above with reference to FIG. 7.

The third guard contact 1305 may be connected to the second guard conductive layer 1304 by penetrating the third insulating layer 305 and the second interlayer insulating layer 304. The third guard conductive layer 1306 may be connected to the third guard contact 1305. The upper surface of the third guard conductive layer 1306 may form the same or substantially the same plane as the upper surface of the third insulating layer 305. The third guard contact 1305 and the third guard conductive layer 1306 may be disposed at the same layers as the third contact 705 and the third conductive layer 706, respectively, described above with reference to FIG. 7.

The fourth guard contact 1307 may be connected to the third guard conductive layer 1306 by penetrating the fourth insulating layer 307 and the third interlayer insulating layer 306. The fourth guard conductive layer 1308 may be connected to the third guard contact 1307. The lower surface of the fourth guard conductive layer 1308 may form the same or substantially the same plane as the lower surface of the first passivation layer 311.

The first guard contact 1301, the first guard conductive layer 1302, the second guard contact 1303, the second guard conductive layer 1304, the third guard contact 1305, the third guard conductive layer 1306, the fourth guard contact 1307 and the fourth guard conductive layer 1308 may include a conductive material such as metal, metal oxide, metal nitride, metal silicide, polysilicon, conductive carbon or a combination thereof.

Referring to FIG. 13, the first redistribution conductive layer 331 may be connected to the fourth guard conductive layer 1308. The lower surface of the first redistribution conductive layer 331 may contact an upper surface 1308US of the fourth guard conductive layer 1308. In an embodiment, portions of the first redistribution conductive layer 331 may be disposed spaced apart from each other in one redistribution trench 200. In an embodiment, at least a portion of the upper surface 1308US of the fourth guard conductive layer 1308 may be exposed.

An upper surface 331US of the first redistribution conductive layer 331 may be located between an upper surface 320US of the redistribution insulating layer 320 and the upper surface 1308US of the fourth guard conductive layer 1308.

Referring to FIG. 14, in an embodiment, the second redistribution conductive layer 332 might not be connected to the fourth guard conductive layer 1308. The lower surface of the second redistribution conductive layer 332 may contact the first passivation layer 311. However, the embodiments of the present disclosure are not limited thereto, and in some embodiments, the lower surface of the second redistribution conductive layer 332 may contact the upper surface 1308US of the fourth guard conductive layer 1308. In an embodiment, portions of the second redistribution conductive layer 332 may be disposed spaced apart from each other in one redistribution trench 200. In an embodiment, at least a portion of the upper surface 1308US of the fourth guard conductive layer 1308 may be exposed.

An upper surface 332US of the second redistribution conductive layer 332 may be located between the upper surface 320US of the redistribution insulating layer 320 and the upper surface 1308US of the fourth guard conductive layer 1308.

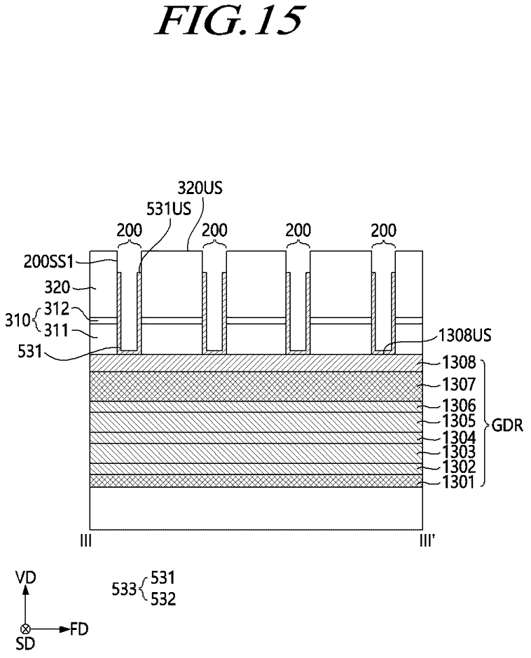

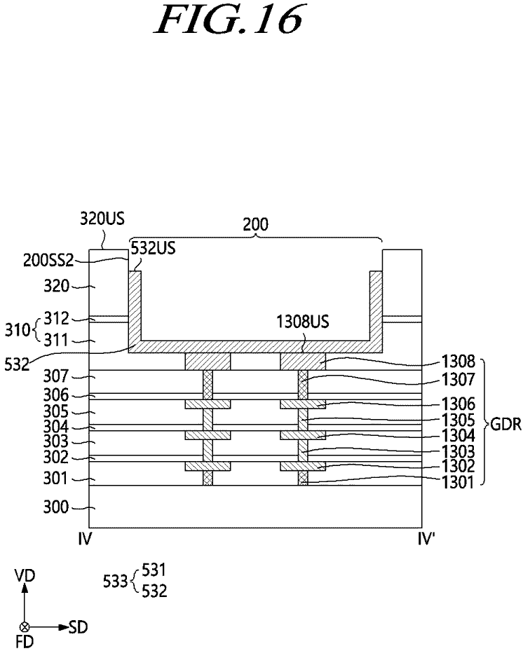

FIG. 15 is a simplified schematic view illustrating another cross-sectional structure of the part indicated by the line III-III′ of FIG. 12. FIG. 16 is a simplified schematic view illustrating another cross-sectional structure of the part indicated by the line IV-IV′ of FIG. 12.

Referring to FIG. 15 and FIG. 16, a semiconductor device according to an embodiment of the present disclosure may include a substrate 300, a first insulating layer 301, a first interlayer insulating layer 302, a second insulating layer 303, a second interlayer insulating layer 304, a third insulating layer 305, a third interlayer insulating layer 306, a fourth insulating layer 307, a passivation layer 310, a redistribution insulating layer 320, and a redistribution conductive layer 533. The passivation layer 310 may include a first passivation layer 311 and a second passivation layer 312. The redistribution conductive layer 533 may include a first redistribution conductive layer 531, a second redistribution conductive layer 532, and the guard ring GDR.

The guard ring GDR may include a first guard contact 1301, a first guard conductive layer 1302, a second guard contact 1303, a second guard conductive layer 1304, a third guard contact 1305, a third guard conductive layer 1306, a fourth guard contact 1307, and a fourth guard conductive layer 1308.

Referring to FIG. 15, in an embodiment, the first redistribution conductive layer 531 may completely cover a lower surface of the redistribution trench 200. The side surface of the first redistribution conductive layer 531 may contact the side surface of the redistribution insulating layer 320, the side surface of the second passivation layer 312, and the side surface of the first passivation layer 311. The lower surface of the first redistribution conductive layer 531 may contact the fourth guard conductive layer 1308. In an embodiment, an upper surface 1308US of the fourth guard conductive layer 1308 might not be exposed.

An upper surface 531US of the first redistribution conductive layer 531 may be located between an upper surface 320US of the redistribution insulating layer 320 and the upper surface 1308US of the fourth guard conductive layer 1308. In an embodiment, an upper surface 531US of the first redistribution conductive layer 531 may be located between an upper surface 320US of the redistribution insulating layer 320 and a lower surface of redistribution insulating layer 320.

Referring to FIG. 16, in an embodiment, the second redistribution conductive layer 532 may completely cover the lower surface of the redistribution trench 200. The side surface of the second redistribution conductive layer 532 may contact the side surface of the redistribution insulating layer 320, the side surface of the second passivation layer 312, and the side surface of the first passivation layer 311. The lower surface of the second redistribution conductive layer 532 may contact the fourth guard conductive layer 1308.

An upper surface 532US of the second redistribution conductive layer 532 may be located between the upper surface 320US of the redistribution insulating layer 320 and the upper surface 1308US of the fourth guard conductive layer 1308. In an embodiment, the upper surface 532US of the second redistribution conductive layer 532 may be located between the upper surface 320US of the redistribution insulating layer 320 and the lower surface of the redistribution insulating layer 320.

Referring again to FIG. 1 and FIG. 11, the redistribution trench 200 may be located in the chip region CHR. The redistribution trench 200 may be disposed in the peripheral region PR or the guard ring region GR. The redistribution trench 200 may be a key that is used to align an etch mask in the process of etching the redistribution conductive layer 333.

According to embodiments of the present disclosure, because the redistribution trench 200 is not disposed in the scribe lane region SR, when performing a process of cutting a wafer to divide semiconductor chips, a cutting defect that occurs as a cutting line crosses the redistribution trench 200 may be minimized.

While detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope. Furthermore, the embodiments may be combined to form additional embodiments.

What is claimed is:

1. A semiconductor device comprising:
a substrate including a chip region;
a passivation layer located on the substrate;
a redistribution insulating layer on the passivation layer;
redistribution trenches located in the chip region, extending through the redistribution insulating layer into the passivation layer, and disposed spaced apart from each other in a first direction of an upper surface of the substrate; and
a redistribution conductive layer disposed on side surfaces of the redistribution trenches, and including an upper surface that is located between an upper surface of the redistribution insulating layer and lower surfaces of the redistribution trenches.

2. The semiconductor device according to claim 1, wherein
the chip region includes a cell region and a peripheral region around the cell region, and
wherein the redistribution trenches are disposed in the peripheral region.

3. The semiconductor device according to claim 1, wherein the width of the redistribution trenches in the first direction is less than the width of the redistribution trenches in a second direction intersecting the first direction.

4. The semiconductor device according to claim 1, wherein the redistribution conductive layer is disposed spaced apart from each other.

5. The semiconductor device according to claim 1, wherein the redistribution conductive layer completely covers the lower surfaces of the redistribution trenches.

6. The semiconductor device according to claim 1, further comprising
a conductive layer disposed under the redistribution trenches,
wherein the redistribution conductive layer contacts an upper surface of the conductive layer.

7. The semiconductor device according to claim 1,
wherein the chip region includes a cell region, a peripheral region around the cell region, and a guard ring region around the peripheral region,
wherein the semiconductor device further comprises a guard ring disposed in the guard ring region, and
wherein the redistribution trenches overlap the guard ring.

8. The semiconductor device according to claim 7, wherein the guard ring includes a guard conductive layer that is disposed under the redistribution trenches, and at least a portion of the redistribution conductive layer contacts an upper surface of the guard conductive layer.

9. The semiconductor device according to claim 8, wherein
the redistribution conductive layer includes a first redistribution conductive layer that is located on first side surfaces of the redistribution trenches facing each other in the first direction and a second redistribution conductive layer that is located on second side surfaces of the redistribution trenches facing each other in the second direction intersecting the first direction, and
wherein the first redistribution conductive layer contacts the upper surface of the guard conductive layer.

10. The semiconductor device according to claim 8, wherein
the redistribution conductive layer includes a first redistribution conductive layer that is located on first side surfaces of the redistribution trenches facing each other in the first direction and a second redistribution conductive layer that is located on second side surfaces of the redistribution trenches facing each other in the second direction intersecting the first direction, and
wherein the second redistribution conductive layer is spaced apart from the guard conductive layer.

11. A semiconductor device comprising:
a substrate including a chip region;
a conductive layer on the substrate;
a passivation layer on the conductive layer;
a redistribution insulating layer on the passivation layer;
redistribution trenches located in the chip region, penetrating the redistribution insulating layer and the passivation layer, and overlapping with the conductive layer; and
a redistribution conductive layer disposed on side surfaces of the redistribution trenches, and including an upper surface that is located between an upper surface of the redistribution insulating layer and lower surfaces of the redistribution trenches.

12. The semiconductor device according to claim 11, wherein a width of the redistribution trenches in a first direction of an upper surface of the substrate is less than a width of the redistribution trenches in a second direction intersecting the first direction.

13. The semiconductor device according to claim 11, wherein the redistribution conductive layer is disposed spaced apart from each other.

14. The semiconductor device according to claim 11, wherein the redistribution conductive layer contacts an upper surface of the conductive layer.

15. The semiconductor device according to claim 11,
wherein the chip region includes a cell region, a peripheral region around the cell region, and a guard ring region around the peripheral region,
wherein the semiconductor device further comprises a guard ring disposed in the guard ring region, and
wherein the redistribution trenches overlap the guard ring.

16. The semiconductor device according to claim 15, wherein the guard ring includes a guard conductive layer that is disposed under the redistribution trenches, and at least a portion of the redistribution conductive layer contacts an upper surface of the guard conductive layer.

17. The semiconductor device according to claim 16, wherein the guard conductive layer is disposed at the same layer as the conductive layer.

18. The semiconductor device according to claim 16, wherein
the redistribution conductive layer includes a first redistribution conductive layer that is located on first side surfaces of the redistribution trenches facing each other in a first direction of an upper surface of the substrate and a second redistribution conductive layer that is located on second side surfaces of the redistribution trenches facing each other in a second direction intersecting the first direction, and
wherein the first redistribution conductive layer contacts the upper surface of the guard conductive layer.

19. The semiconductor device according to claim 16, wherein
the redistribution conductive layer includes a first redistribution conductive layer that is located on first side surfaces of the redistribution trenches facing each other in a first direction of an upper surface of the substrate and a second redistribution conductive layer that is located on second side surfaces of the redistribution trenches facing each other in a second direction intersecting the first direction, and
wherein the second redistribution conductive layer is spaced apart from the guard conductive layer.

20. A semiconductor device comprising:
a conductive layer on a substrate;
a passivation layer on the conductive layer;
a redistribution insulating layer on the passivation layer;
redistribution trenches located in a chip region of the substrate, passing through the redistribution insulating layer and the passivation layer, and overlapping with the conductive layer;
a redistribution conductive layer disposed on side surfaces of the redistribution trenches, the redistribution conductive layer including an upper surface that is located between an upper surface of the redistribution insulating layer and a lower surface of the redistribution trenches, and
a guard ring disposed in a guard ring region of the substrate,
wherein the redistribution trenches overlap with the guard ring, and
wherein the guard ring includes a guard conductive layer that is disposed under the redistribution trenches, and at least a portion of the redistribution conductive layer contacts an upper surface of the guard conductive layer.
